(19) United States
(12) Patent Application Publication
(10) Pub. No.: US 2014/0313667 A1
(43) Pub. Date: Oct. 23, 2014

(54) ELECTRONIC DEVICE WITH FAN MODULE

(71) Applicant: HON HAI PRECISION INDUSTRY CO., LTD., New Taipei (TW)

(72) Inventor: CHENG-HSIU YANG, New Taipei (TW)

(73) Assignee: HON HAI PRECISION INDUSTRY CO., LTD., New Taipei (TW)

(21) Appl. No.: 13/975,353

(22) Filed: Aug. 25, 2013

(30) Foreign Application Priority Data
Apr. 22, 2013 (TW) 102114158

(51) Int. Cl. H05K 7/20; F04D 29/60; F04D 29/40

(52) U.S. Cl. CPC H05K 7/20554; F04D 29/403; F04D 29/603
USPC 361/695; 417/423.15; 417/423.14

(57) ABSTRACT

An electronic device includes a main body and a number of fan modules. The main body defines a number of vents in a top of the main body. The fan modules are mounted to the top of the main body. Each fan module includes a housing and a fan. The housing includes a side plate defining an opening aligned with the vents. A stop plate is pivotably connected to a first end of the opening, and is operable to cover the opening. The fan is mounted in the housing, and is near a second end of the opening opposite to the first end.

### BACKGROUND

1. Technical Field

The present disclosure relates to an electronic device with fan modules.

2. Description of Related Art

A storage bridge bay generally defines a plurality of vents in an enclosure of the storage bridge bay. A plurality of fans is mounted to an outer surface of the enclosure and is aligned with the vents, for dissipating heat from the storage bridge bay. When one of the fans is broken, airflow out of the storage bridge bay flows through the broken fan and the vents, and into the storage bridge bay; and then is drawn by the other fans in the end.

Therefore, the efficiency of heat dissipation decreases.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electronic device, wherein the electronic device includes a plurality of fan modules.

FIG. 2 is an enlarged view of one of the fan modules of FIG. 1.

FIG. 3 is similar to FIG. 2, but viewed from another perspective.

FIG. 4 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

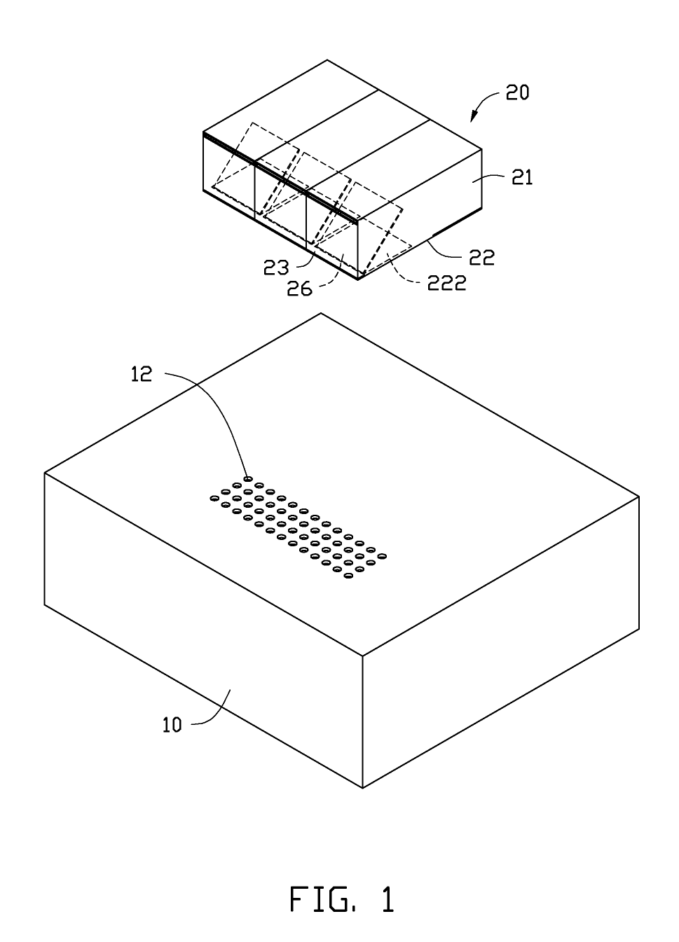

FIG. 1 shows an exemplary embodiment of an electronic device. The electronic device includes a main body 10 and a plurality of fan modules 20. A plurality of vents 12 is defined in a top of the main body 10.

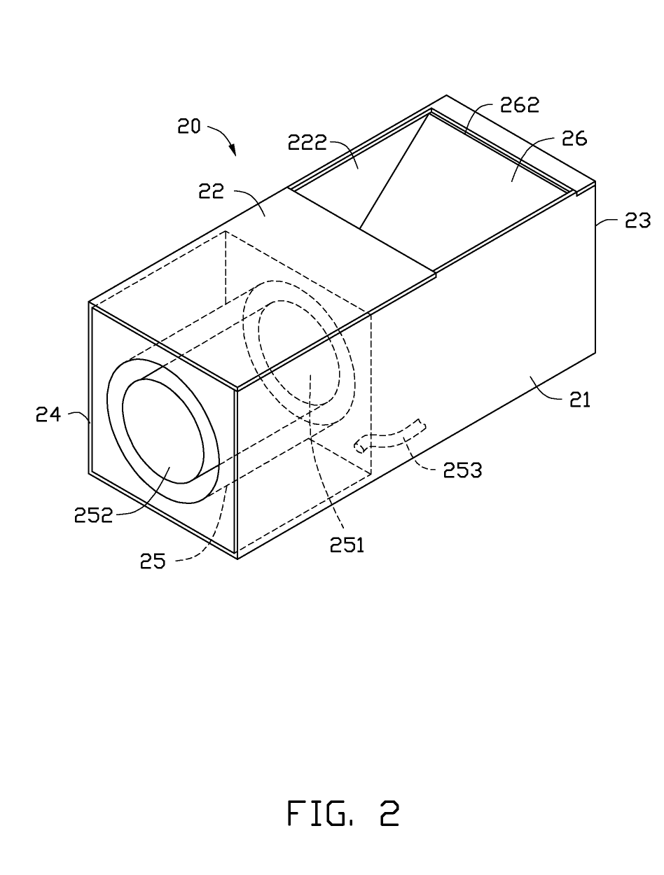

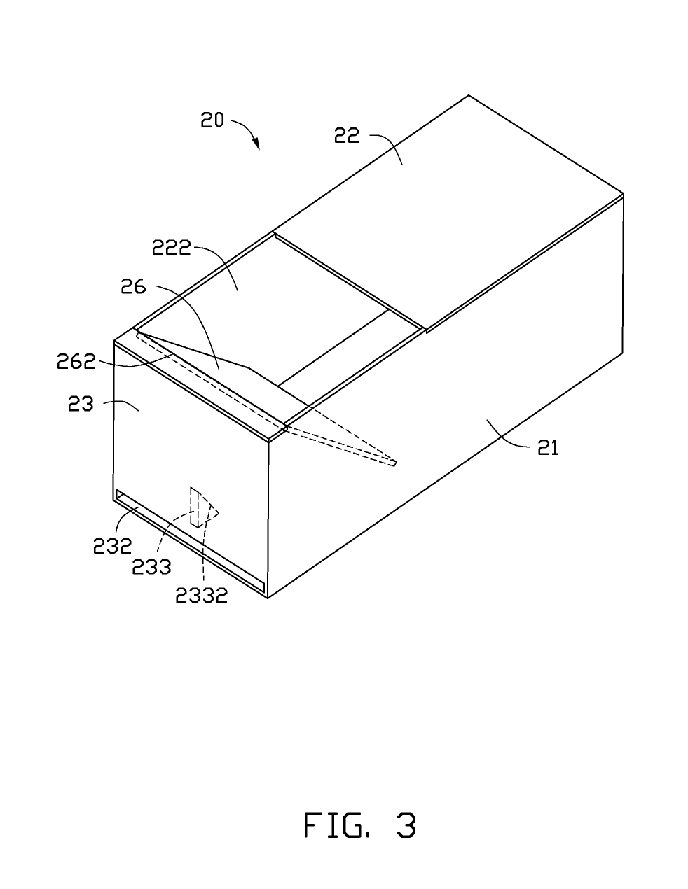

FIGS. 2 and 3 show each fan module 20 including a rectangular and hollow housing 21, and a fan 25 mounted in the housing 21. The housing 21 includes a side plate 22 and an end plate 23 perpendicular to the side plate 22. A mounting hole 24 is defined in the housing 21, opposite to the end plate 23. The fan 25 is near the mounting hole 24. An airflow inlet 251 of the fan 25 faces the end plate 23, an airflow outlet 252 of the fan 25 faces the mounting hole 24. The side plate 22 defines an opening 222. A stop plate 26 is pivotably connected to a first end of the opening 222 adjacent to the end plate 23. The fan 25 is near a second end of the opening 222 opposite to the first end. A through slot 232 is defined in the end plate 23 and is opposite to the opening 222, for a cable 253 of the fan 25 extending through. A wedge-shaped protrusion 233 protrudes from an inner surface of the end plate 23. The protrusion 233 includes a slanting surface 2332 facing the fan 25.

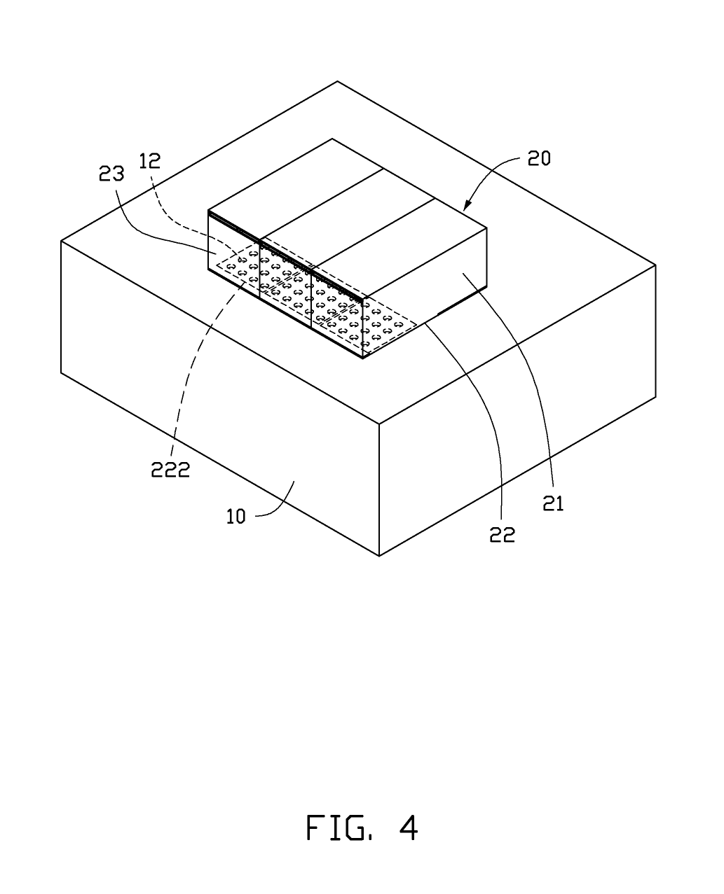

FIG. 4 shows that the fan modules 20 are mounted to the top of the main body 10 to cover the vents 12. The openings 222 are aligned with the vents 12. By force of gravity, the stop plates 26 are rotated down to cover the openings 222. When the fans 25 operate, airflow generated by the fans 25 dissipates heat for the main body 10 and makes the stop plates 26 rotate up. The airflow flows through the vents 12 and the openings 222, and flows out of the fan modules 20 through the mounting holes 24.

When the stop plates 26 are rotated up by the force of the airflow, the stop plates 26 abut against the slanting surfaces 2332 of the protrusions 233, and the distance from a center of gravity of each stop plate 26 to the corresponding end plate 23 is greater than the distance from a pivotal axis 262 of the stop plate 26 to the end plate 23. When the fan 25 of one of the fan modules 20 is broken, the stop plate 26 of the broken fan module 20 can be rotated down to cover the opening 222 by gravity. Airflow out of the electronic device cannot enter the main body 10 through the broken fan module 20 because of being blocked by the stop plate 26, thus, the heat dissipation effect of the unbroken fan modules 20 is not obstructed.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A fan module, comprising:
a housing comprising a side plate, the side plate defining an opening, a stop plate pivotably connected to a first end bounding the opening and operable to cover or uncover the opening; and
a fan mounted in the housing and near a second end of the opening opposite to the first end.

2. The fan module of claim 1, wherein the housing further comprises an end plate perpendicular to the side plate and near the first end of the opening, a mounting hole is defined in the housing and is opposite to the end plate, an airflow inlet of the fan faces the end plate, an airflow outlet of the fan faces the mounting hole.

3. The fan module of claim 2, wherein a protrusion protrudes from an inner surface of the end plate, the stop plate is operable to rotate to abut against the protrusion.

4. The fan module of claim 3, wherein the protrusion is wedge-shaped, comprising a slanting surface facing the fan.

5. The fan module of claim 2, wherein the end plate defines a through slot opposite to the opening, for a cable of the fan extending through.

6. An electronic device, comprising:
a main body defining a plurality of vents in a top of the main body; and
a plurality of fan modules mounted to the top of the main body, each fan module comprising:
a housing comprising a side plate, the side plate defining an opening aligning with the vents, a stop plate pivotably connected to a first end bounding the opening and operable to cover or uncover the opening; and
a fan mounted in the housing and near a second end of the opening opposite to the first end.

7. The electronic device of claim 6, wherein the housing of each fan module further comprises an end plate perpendicular to the side plate and near the first end of the opening, a mounting hole is defined in the housing and is opposite to the end plate, an airflow inlet of the fan faces the end plate, an airflow outlet of the fan faces the mounting hole.

8. The electronic device of claim 7, wherein a protrusion protrudes from an inner surface of the end plate, the stop plate is operable to rotate to abut against the protrusion.

9. The electronic device of claim 8, wherein the protrusion is wedge-shaped, comprising a slanting surface facing the fan.

10. The electronic device of claim 7, wherein the end plate defines a through slot opposite to the opening, for a cable of the fan extending through.
